(19) United States
(12) Patent Application Publication
(10) Pub. No.: US 2015/0155268 A1
(43) Pub. Date: Jun. 4, 2015

(54) SEMICONDUCTOR PACKAGE DEVICE

(71) Applicant: TAEJOO HWANG, Yongin-si (KR)

(72) Inventor: TAEJOO HWANG, Yongin-si (KR)

(21) Appl. No.: 14/474,121

(22) Filed: Aug. 30, 2014

(30) Foreign Application Priority Data
Dec. 3, 2013 (KR) 10-2013-0149215

(51) Int. Cl. H01L 25/065

(52) U.S. Cl. CPC H01L 25/0657; H01L 2225/0651; H01L 2225/06517

(57) ABSTRACT

A semiconductor package device, comprising: a package substrate having a first width; first and second semiconductor packages sequentially mounted on the package substrate; and a connection structure connecting the first and second semiconductor packages electrically to each other. The first semiconductor package comprises: a first substrate facing the package substrate and having a second width smaller than the first width; a first semiconductor chip between the first substrate and the package substrate; a conductive structure electrically connecting the first semiconductor chip to the package substrate; and a bonding wire electrically connecting the first substrate to the first semiconductor chip.

### CROSS-REFERENCE TO RELATED APPLICATIONS

This U.S. non-provisional patent application claims priority under 35 U.S.C. §119 to Korean Patent Application No. 10-2013-0149215, filed on Dec. 3, 2013, in the Korean Intellectual Property Office, the entire contents of which are hereby incorporated by reference.

### BACKGROUND OF THE INVENTION

This disclosure relate to a semiconductor package device, and in particular, to a semiconductor package device of package-on-package (PoP) structure.

Due to a small-size, multifunctionality, and/or low-cost characteristics, semiconductor devices are considered important elements in the electronics industry. Some semiconductor devices can be generally classified into a memory device for storing data, a logic device for processing data, and a hybrid device capable of performing various functions.

Higher integration and higher speeds of semiconductor devices are required to satisfy consumer demands for electronic devices with higher densities and faster speeds. A variety of studies are being conducted to achieve such requirements, i.e., to increase the integration density and performance of semiconductor devices.

### SUMMARY

An embodiment includes a semiconductor package device, comprising: a package substrate having a first width; first and second semiconductor packages sequentially mounted on the package substrate; and a connection structure connecting the first and second semiconductor packages electrically to each other. The first semiconductor package comprises: a first substrate facing the package substrate and having a second width smaller than the first width; a first semiconductor chip between the first substrate and the package substrate; a conductive structure electrically connecting the first semiconductor chip to the package substrate; and a bonding wire electrically connecting the first substrate to the first semiconductor chip.

An embodiment includes a semiconductor package device, comprising: a first semiconductor package including: a first substrate; and a first semiconductor chip mounted on the first substrate; a second semiconductor package including: a second substrate; and a second semiconductor chip mounted on the second substrate; and a package substrate. The first semiconductor chip is electrically connected to the second semiconductor chip through the first substrate and the second substrate; and the first semiconductor chip is electrically connected to the package substrate.

An embodiment includes a system, comprising: a processor; and a memory coupled to the processor, the memory including: a first semiconductor package including: a first substrate; and a first semiconductor chip mounted on the first substrate; a second semiconductor package including: a second substrate; and a second semiconductor chip mounted on the second substrate; and a package substrate. The first semiconductor chip is electrically connected to the second semiconductor chip through the first substrate and the second substrate; and the first semiconductor chip is electrically connected to the package substrate.

### BRIEF DESCRIPTION OF THE DRAWINGS

Embodiments will be more clearly understood from the following brief description taken in conjunction with the accompanying drawings. The accompanying drawings represent non-limiting embodiments as described herein.

FIG. 1 is a sectional view illustrating a semiconductor package device according to some embodiments.

FIGS. 2A through 2G are sectional views illustrating a method of fabricating a semiconductor package device according to some embodiments.

FIG. 3 is a sectional view illustrating an example of a package module including a semiconductor package device according to some embodiments.

FIG. 4 is a schematic view of an electronic system which may include a semiconductor package device according to an embodiment.

### DETAILED DESCRIPTION

Embodiments will now be described more fully with reference to the accompanying drawings. Embodiments of the inventive concepts may, however, take different forms and should not be construed as being limited to the particular embodiments set forth herein; rather, these embodiments are provided so that this disclosure will be thorough and complete, and will fully convey the concept of some embodiments to those of ordinary skill in the art. In the drawings, the thicknesses of layers and regions are exaggerated for clarity. Like reference numerals in the drawings denote like elements, and thus their description will be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of some embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of all embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Unless otherwise defined, all terms (including technical and scientific terms) used herein have the same meaning as commonly understood by one of ordinary skill in the art to which some embodiments of the inventive concepts belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

It should be noted that the figures are intended to illustrate the general characteristics of methods, structure and/or materials utilized in certain some embodiments and to supplement the written description provided below. The drawings may not, however, be to scale and may not precisely reflect the precise structural or performance characteristics of any given embodiment, and should not be interpreted as defining or limiting the range of values or properties encompassed by some embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

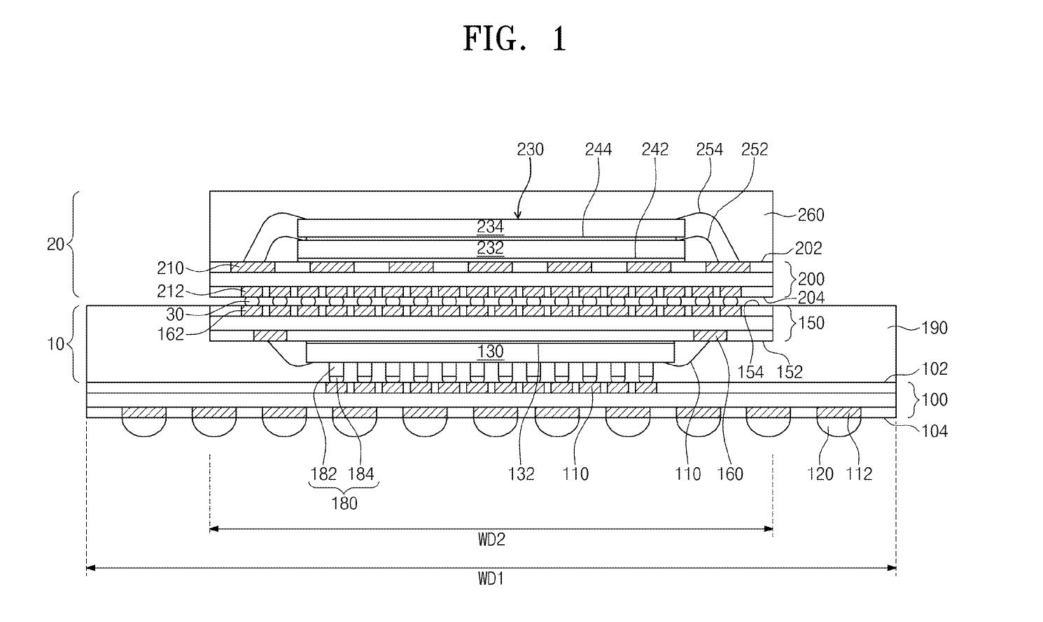

FIG. 1 is a sectional view illustrating a semiconductor package device according to some embodiments.

Referring to FIG. 1, a semiconductor package device may include a package substrate 100, a first semiconductor package 10 and a second semiconductor package 20 mounted on the package substrate 100, and a connection structure 30 electrically connecting the first and second semiconductor packages 10 and 20 to each other.

In some embodiments, the first semiconductor package 10 may be of a different type from the second semiconductor package 20. For example, the first semiconductor package 10 may be a logic package, and the second semiconductor package 20 may be a memory package; however, in other embodiments the first semiconductor package 10 and the second semiconductor package 20 may be configured to perform different functions, include different circuits, or the like.

The package substrate 100 may be a printed circuit board (PCB) or other substrate on which semiconductor packages may be mounted. The package substrate 100 may include a first surface 102 and a second surface 104 that are opposite to each other. For example, the first surface 102 may face the first semiconductor package 10, and the second surface 104 may be spaced apart from the first semiconductor package 10 and face an opposite direction. Multiple first pads 110 may be disposed at the first surface 102, and multiple second pads 112 may be disposed at the second surface 104. The second pads 112 may be electrically connected to external terminals 120, respectively. Each of the external terminals 120 may include, for example, a solder ball or other structure suitable for making an electrical connection to the second pads 112. In certain embodiments, the package substrate 100 may have a first width WD1.

The first semiconductor package 10 may include a first substrate 150, a first semiconductor chip 130, first connection patterns 170 and 180, and a first molding part 190.

The first substrate 150 may be a printed circuit board (PCB), a silicon substrate, or other substrate suitable for mounting semiconductor chips. In some aspects, the first substrate 150 may be disposed between the first semiconductor chip 130 and a second semiconductor chip 230, which will be subsequently described, to electrically connect the first and second semiconductor chips 130 and 230 to each other. That is, the first substrate 150 may serve as an interposer substrate. In some embodiments, the first substrate 150 may have a second width WD2 smaller than the first width WD1.

As the width of the first substrate 150 decreases, a cost of the first substrate 150 may decrease. In this sense, if a first substrate 150 with a width that is smaller than that of the package substrate 100 is used, a fabrication cost of the semiconductor package device may be reduced.

The first substrate 150 may include a first surface 152 on which the first semiconductor chip 130 is mounted, and a second surface 154 opposite to the first surface 152. The first semiconductor chip 130 may be attached on the first surface 152 by a die attach film (DAF) 132 or other similar bonding material. Third pads 160 may be disposed at the first surface 152 of the first substrate 150 to be electrically connected to the first semiconductor chip 130. Fourth pads 162 may be disposed at the second surface 154 of the first substrate 150 and may be electrically connected to the connection structure 30. In some embodiments, the arrangement and number of the fourth pads 162 may be substantially the same as those of the connection structure 30.

The first semiconductor chip 130 may include an active surface provided with a circuit pattern and a non-active surface opposite to the active surface. The active surface of the first semiconductor chip 130 may be spaced apart from the package substrate 100 and face the first surface of the package substrate 100. The non-active surface of the first semiconductor chip 130 may be attached to the first substrate 150 by the DAF 132.

In some embodiments, the circuit pattern of the first semiconductor chip 130 may include logic cells. For example, the logic cells may be part of a circuit configured to control memory cells of one or more other semiconductor chips.

The first connection patterns 170 and 180 may be disposed on the first semiconductor chip 130 and the package substrate 100. The use of the first connection patterns 170 and 180 makes it possible to connect electrically the first semiconductor chip 130, first substrate 150 and the package substrate 100 to each other.

In some embodiments, the first connection patterns 170 and 180 may include bonding wires 170 and bump structures 180. Each of the bump structures 180 may include a conductive post 182 and a solder ball 184, which are coupled or jointed to each other. In some embodiments, the bonding wires 170 may be disposed at an edge region of the first semiconductor chip 130. Each of the afore-described third pads 160 may be electrically connected to the first semiconductor chip 130 via the bonding wires 170. In some embodiments, the third pads 160 may be disposed at the edge region of the first substrate 150.

The bump structures 180 may be disposed at regions of the first semiconductor chip 130 where the bonding wires 170 are not disposed. For example, the bump structures 180 may be disposed at a central region of the first semiconductor chip 130. Each of the bump structures 180 may be provided to be in contact with a corresponding one the first pads 110 of the package substrate 100. The package substrate 100 and the first semiconductor chip 130 may be electrically connected to each other by the bump structures 180.

In some embodiments, the first semiconductor chip 130 may be mounted on the package substrate 100 in a flip-chip bonding manner using the bump structures 180 and may be electrically connected to the first substrate 150 using the bonding wires 170. As a result, the I/O density of the semiconductor package device may be increased. In particular, the stacked packages in a conventional package-on-package structure may be connected to each other by solder balls, but in some embodiments, the first and second semiconductor packages 10 and 20 may be electrically connected to each other by the first substrate 150 and the bonding wires 170. As the size of the semiconductor package device is decreases, using bonding wires 170 to connect the packages may be more advantageous than the conventional way of using the solder balls, in terms of area. Further, connecting the first semiconductor chip 130 electrically to the package substrate 100 in a flip-chip manner using the bump structures 180 makes it possible to increase the I/O density of the semiconductor package device.

The first molding part 190 may be disposed on the package substrate 100 to protect the first semiconductor chip 130 and the first substrate 150. The first molding part 190 may have a top surface that is substantially coplanar with, for example, the second surface 154 of the first substrate 150.

The second semiconductor package 20 may include a second substrate 200, a second semiconductor chip 230, second connection patterns 252 and 254, and a second molding part 260.

The second substrate 200 may include a PCB, a semiconductor substrate, or other substrate on which semiconductor chips may be mounted. The second substrate 200 may include a first surface 202, on which the second semiconductor chip 230 is mounted, and a second surface 204 opposite to the first surface 202. Multiple fifth pads 210 may be disposed at the first surface 202 of the second substrate 200, and multiple sixth pads 212 may be disposed at the second surface 204 of the second substrate 200.

An embodiment will be described in which the second semiconductor chip 230 includes two stacked semiconductor chips. For concise description, hereinafter, a lower one of the two stacked semiconductor chips of the second semiconductor chip 230 will be referred to as a lower chip 232, and an upper one will be referred to as an upper chip 234. However, in other embodiments, the number of semiconductor chips constituting the second semiconductor chip 230 may be different, such a one semiconductor chip or three or more semiconductor chips.

The lower chip 232 may be attached on the first surface of the second substrate 200 by a first DAF 242 or other similar bonding material. The upper chip 234 may be attached on the lower chip 232 by a second DAF 244 or other similar bonding material. In this embodiment, the lower and upper chips 232 and 234 may be vertically stacked, but in other some embodiments, they may be disposed to be horizontally spaced apart from each other or in other configurations.

The second connection patterns 252 and 254 may include a lower chip connection pattern 252 electrically connecting the lower chip 232 with the fifth pads 210 and an upper chip connection pattern 254 electrically connecting the upper chip 234 with the fifth pads 210. For example, the second connection patterns 252 and 254 may be provided in the form of a bonding wire.

In some embodiments, the second semiconductor chip 230 may include memory cells. As described above, the first and second semiconductor packages 10 and 20 may be of different types from each other and as a result, constitute a heterogeneous package structure.

The second molding part 260 may be formed on the second substrate 200 to protect the second semiconductor chip 230 and the second substrate 200 against harmful external influences.

The connection structures 30 may be disposed between the first and second semiconductor packages 10 and 20 to connect the first and second semiconductor packages 10 and 20 electrically to each other. For example, each of the connection structures 30 may be disposed to be in contact with a corresponding fourth pad 162 of the first substrate 150 and a corresponding sixth pad 212 of the second substrate 200. In some embodiments, the connection structure 30 may be a solder ball.

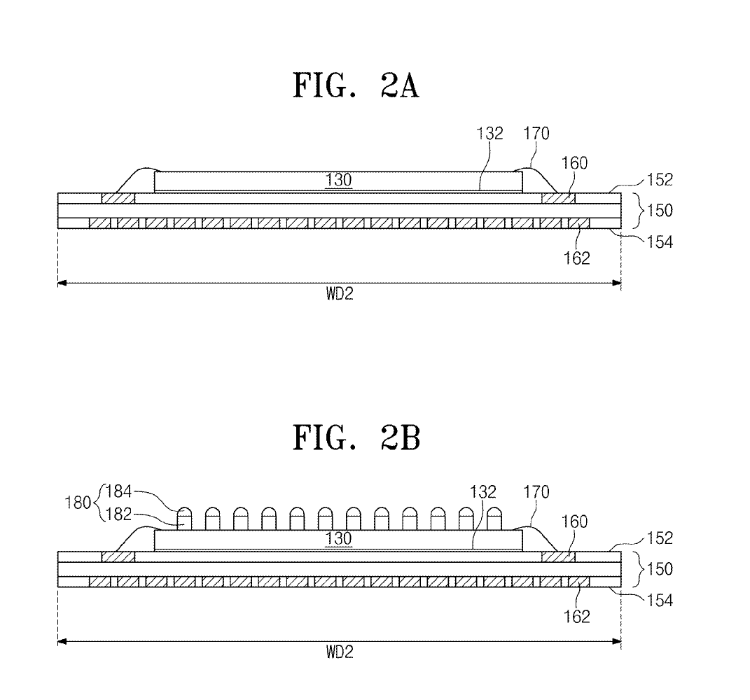

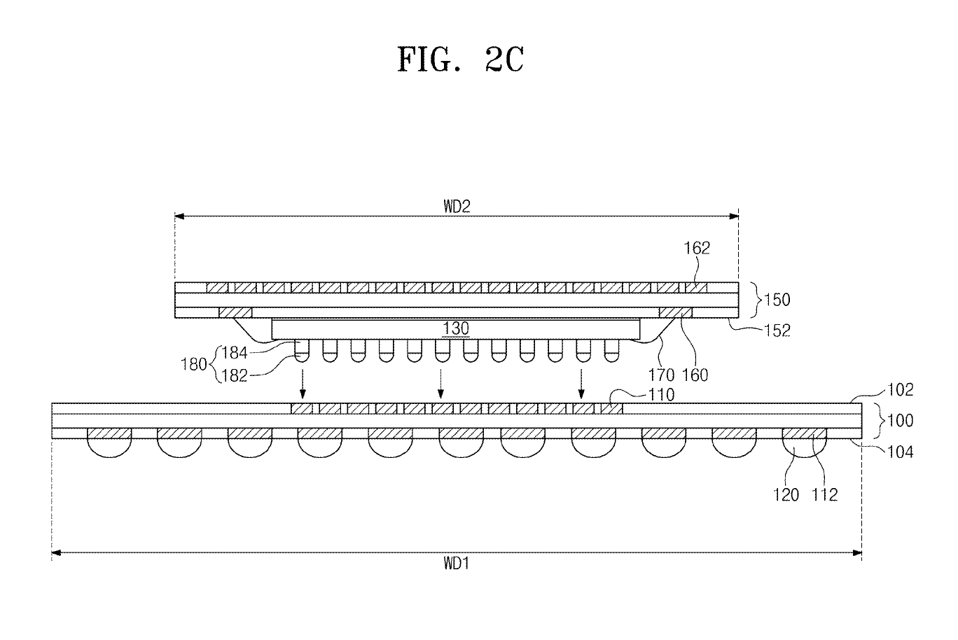

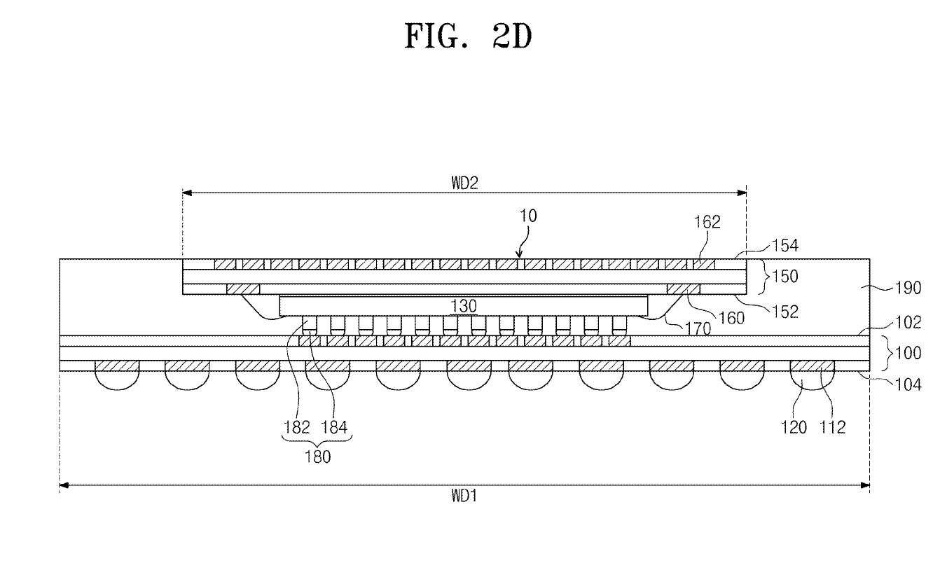

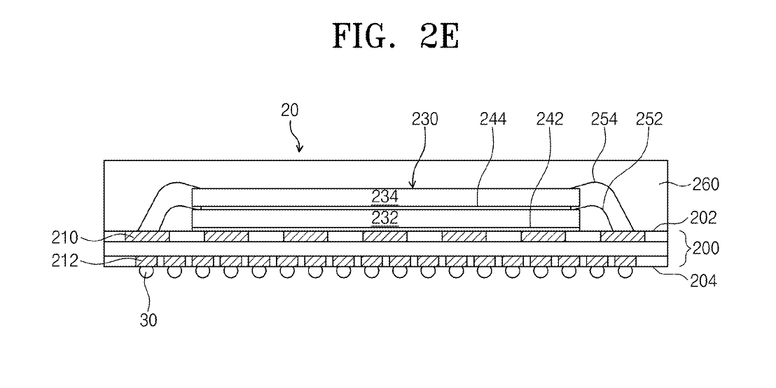

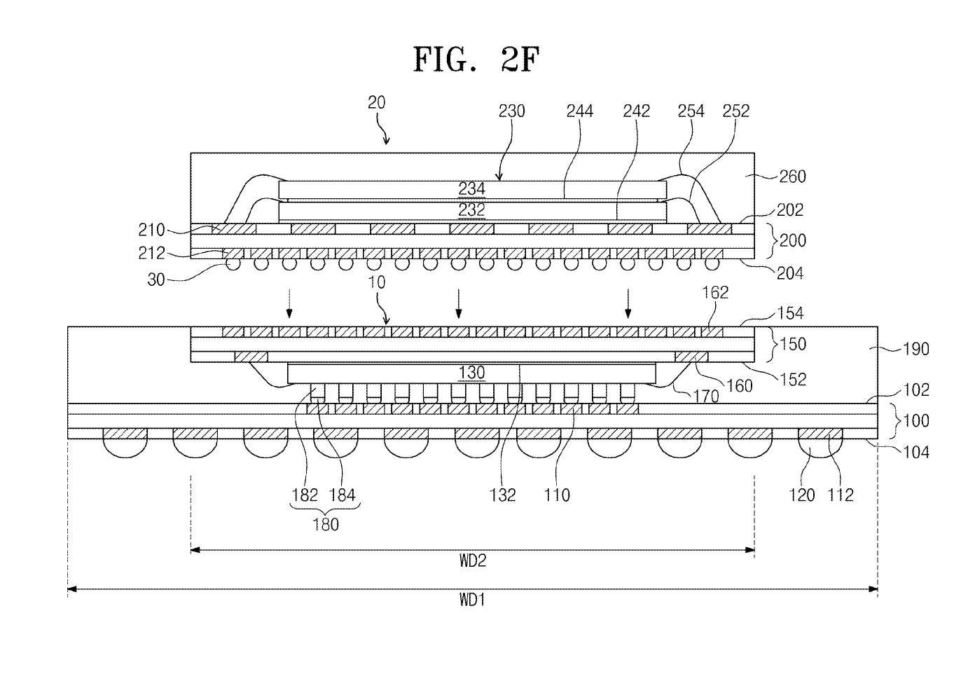

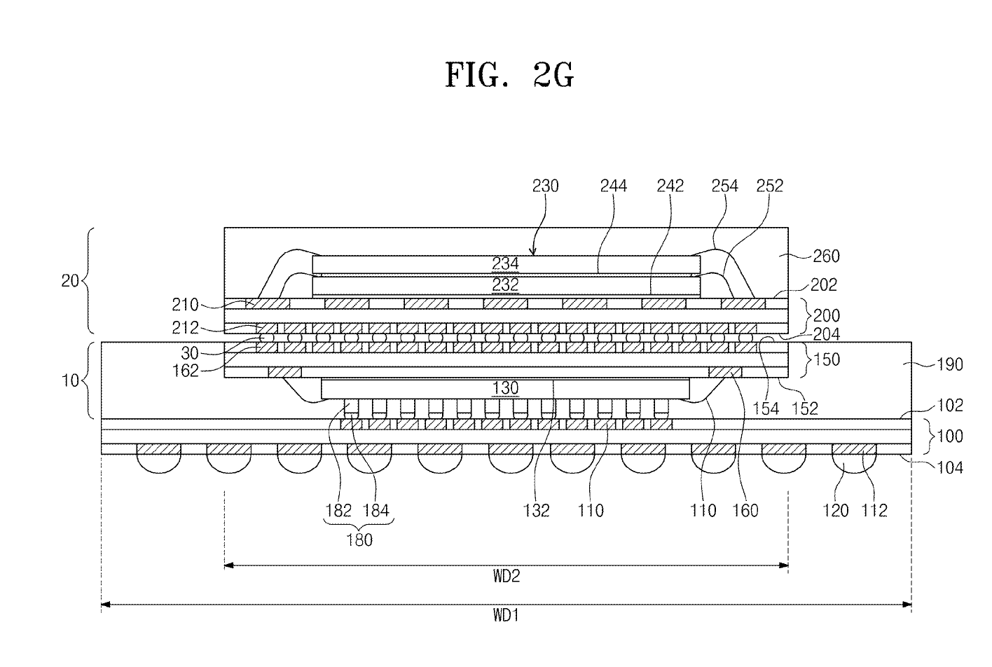

FIGS. 2A through 2G are sectional views illustrating a method of fabricating a semiconductor package device according to some embodiments.

Referring to FIG. 2A, a first semiconductor chip 130 may be mounted on a first substrate 150.

The first semiconductor chip 130 may be attached to a first surface 152 of the first substrate 150 by a DAF 132 or other similar bonding material. The DAF 132 may be attached to be in contact with a non-active surface of the first semiconductor chip 130.

The first substrate 150 and the first semiconductor chip 130 may be electrically connected to each other by bonding wires 170. As an example, of third pads 160 may be formed on, in, or adjacent to the first surface 152 of the first substrate 150. The bonding wires 170 may be formed to connect the first semiconductor chip 130 to the third pads 160. The bonding wires 170 may be connected to an active surface of the first semiconductor chip 130.

Fourth pads 162 may be formed on, in, or adjacent to a second surface 154 of the first substrate 150.

In some embodiments, the first substrate 150 may have a second width WD2.

Referring to FIG. 2B, bump structures 180 may be formed on an active surface of the first semiconductor chip 130.

In some embodiments, each of the bump structures 180 may include a conductive post 182 and a solder ball 184, which are coupled or jointed to each other. The conductive post 182 may include a metallic material (e.g., copper), or other conductive material.

As shown, the bump structures 180 and the bonding wires 170 may be formed on the active surface of the first semiconductor chip 130. In some embodiments, the bonding wires 170 may be formed on an edge region of the first semiconductor chip 130, and the bump structures 180 may be formed on a central region of the first semiconductor chip 130.

Referring to FIG. 2C, the first semiconductor chip 130 may be disposed in such a way that the active surface thereof faces the first surface 102 of the package substrate 100. The first semiconductor chip 130 and the first substrate 150 may then be mounted on the package substrate 100.

The first pads 110 may be formed on the first surface 102 of the package substrate 100. The first pads 110 may be disposed at positions corresponding to the bump structures 180, when viewed in a plan view.

In some embodiments, the package substrate 100 may have a first width WD1 that is larger than the second width WD2.

Referring to FIG. 2D, a first molding part 190 may be formed on the package substrate 100 to protect the first semiconductor chip 130 and the first substrate 150. The first molding part 190 may be formed to have a top surface that is substantially coplanar with, for example, the second surface 154 of the first substrate 150.

In some embodiments, second pads 112 may be formed on the second surface 104 of the package substrate 100. The second pads 112 may be electrically connected to the external terminals 120.

In some embodiments, the process of attaching the external terminals 120 to the second pads 112 may be performed in a subsequent process.

Referring to FIG. 2E, a second semiconductor package 20 may be provided. For example, a second semiconductor chip 230 may be attached to a first surface 202 of a second substrate 200, on which fifth pads 210 are provided, using DAFs 242 and 244. In some embodiments, as illustrated in FIG. 2E, the second semiconductor chip 230 may have a vertically-stacked multi-chip structure including a lower chip 232 and an upper chip 234. Further, two second semiconductor chips are illustrated as an example of the second semiconductor chip 230, but the number of the semiconductor chips constituting the second semiconductor chip 230 may be different as described above.

The lower chip 232 may be attached on the first surface 202 of the second substrate 200 by the first DAF 242, and the upper chip 234 may be attached on the lower chip 232 by the second DAF 244. The upper and lower chips 234 and 232 may be electrically connected to the fifth pads 210 via the second connection patterns 252 and 254, respectively.

The second molding part 260 may be formed on the second substrate 200 to protect the second semiconductor chip 230 against harmful external influences. The second molding part 260 may be formed to cover wholly a top surface of the second semiconductor chip 230.

Sixth pads 212 may be formed on, in, or adjacent to the second surface 204 of the second substrate 200. Connection structures 30 may be electrically connected to the sixth pads 212, respectively. In some embodiments, each of the connection structures 30 may be formed in the form of a solder ball.

Referring to FIGS. 2F and 2G, the second semiconductor package 20 may be mounted on the first substrate 150.

The connection structures 30 disposed on the second surface 204 of the second substrate 200 may be disposed to face fourth pads 162 of the first substrate 150. The connection structures 30 may then be brought in contact with the fourth pads 162.

As a result, a semiconductor package device may be fabricated to include the first and second semiconductor packages 10 and 20 mounted on the package substrate 100.

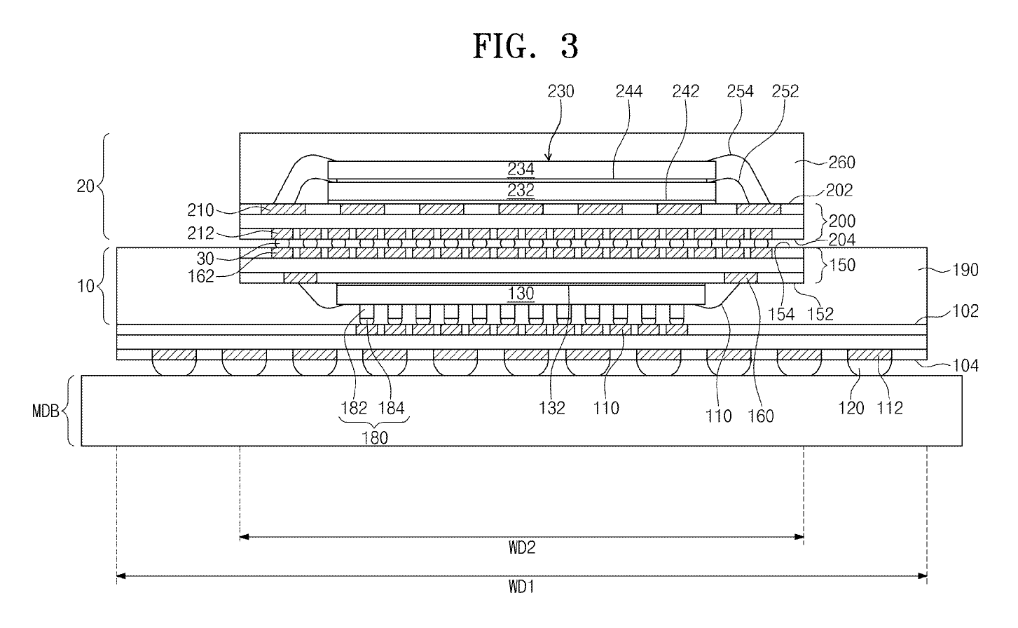

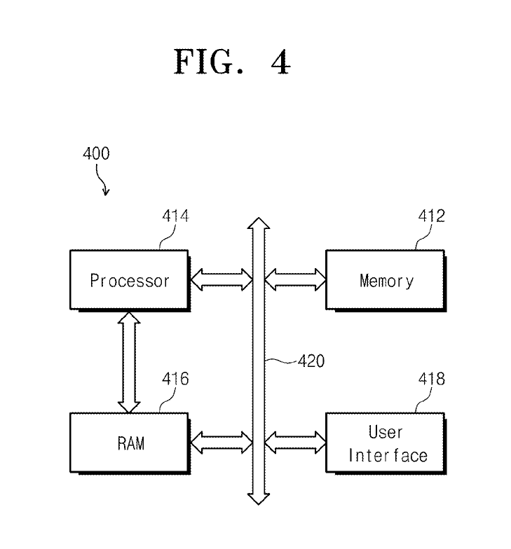

FIG. 3 is a sectional view illustrating an example of a package module including a semiconductor package device According to some embodiments. Referring to FIG. 3, the module may include a module board MDB and a semiconductor package device.

The module board MDB may be provided in, or a part of an electronic device. The semiconductor package device may be disposed on and connected to the module board MDB. The semiconductor package device according to some embodiments may be substantially the same as a semiconductor package device shown in FIG. 1, and thus, in order to avoid redundancy, a detailed explanation thereof will be omitted. The external terminals 120, which are connected to the package substrate 100 of the semiconductor package device, may be connected to the module board MDB.

In FIG. 3, description of previously described elements identified having the same reference number as those described above will be omitted for the sake of brevity.

According to some embodiments, provided is a semiconductor package device of package-on-package structure. In the device, a first substrate serving as an interposer is provided to have a width smaller than that of a package substrate, and this leads to a reduction in cost of the interposer. Further, a first semiconductor chip may be mounted on the package substrate in a flip-chip manner, and it may be connected to the first substrate using bonding wires, thereby having an increased I/O density.

FIG. 4 is a schematic view of an electronic system which may include a semiconductor package device according to an embodiment. The electronic system 400 may be part of a wide variety of electronic devices including, but not limited to portable notebook computers, Ultra-Mobile PCs (UMPC), Tablet PCs, servers, workstations, mobile telecommunication devices, and so on. For example, the electronic system 400 may include a memory system 412, a processor 414, RAM 416, and a user interface 418, which may execute data communication using a bus 420.

The processor 414 may be a microprocessor or a mobile processor (AP). The processor 414 may have a processor core (not illustrated) that can include a floating point unit (FPU), an arithmetic logic unit (ALU), a graphics processing unit (GPU), and a digital signal processing core (DSP Core), or any combinations thereof. The processor 414 may execute the program and control the electronic system 400.

The RAM 416 may be used as an operation memory of the processor 414. Alternatively, the processor 414 and the RAM 416 may be packaged in a single package body.

The user interface 418 may be used in inputting/outputting data to/from the electronic system 400. The memory system 412 may store codes for operating the processor 414, data processed by the processor 414, or externally input data. The memory system 412 may include a controller and a memory. The memory system may include an interface to computer readable media.

Some embodiments provide a high-density and high-performance semiconductor package device.

In some embodiments, a semiconductor package device may include a package substrate having a first width, first and second semiconductor packages sequentially mounted on the package substrate, and a connection structure connecting the first and second semiconductor packages electrically to each other. The first and second semiconductor packages may include chips of different types from each other. The first semiconductor package may include a first substrate facing the package substrate and having a second width smaller than the first width, a first semiconductor chip between the first substrate and the package substrate, a bump structure electrically connecting the first semiconductor chip to the package substrate, and a bonding wire electrically connecting the first substrate to the first semiconductor chip.

In some embodiments, the bump structure may include a conductive post in contact with an active surface of the first semiconductor chip, and a solder ball attached to the conductive post.

In some embodiments, the bonding wire may be in contact with an active surface of the first semiconductor chip.

In some embodiments, the bonding wire may be provided on an edge region of the first semiconductor chip, and the bump structure may be provided on a central region of the first semiconductor chip.

In some embodiments, the second semiconductor package may include a second substrate electrically connected to the connection structure, a second semiconductor chip mounted on the second substrate, and a second connection pattern electrically connecting the second semiconductor chip to the second substrate.

In some embodiments, the first semiconductor chip may include logic cells, and the second semiconductor chip may include memory cells.

While some embodiments of the inventive concepts have been particularly shown and described, it will be understood by one of ordinary skill in the art that variations in form and detail may be made therein without departing from the spirit and scope of the attached claims.

What is claimed is:

1. A semiconductor package device, comprising:
a package substrate having a first width;
first and second semiconductor packages sequentially mounted on the package substrate; and
a connection structure connecting the first and second semiconductor packages electrically to each other;
wherein the first semiconductor package comprises:
a first substrate facing the package substrate and having a second width smaller than the first width;
a first semiconductor chip between the first substrate and the package substrate;
a conductive structure electrically connecting the first semiconductor chip to the package substrate; and
a bonding wire electrically connecting the first substrate to the first semiconductor chip.

2. The device of claim 1, wherein the conductive structure comprises:
a conductive post in contact with an active surface of the first semiconductor chip; and
a solder ball attached to the conductive post.

3. The device of claim 1, wherein the bonding wire is in contact with an active surface of the first semiconductor chip.

4. The device of claim 1, wherein:
the bonding wire is disposed at an edge region of the first semiconductor chip, and
the conductive structure is disposed at a central region of the first semiconductor chip.

5. The device of claim 1, wherein the second semiconductor package comprises:
a second substrate electrically connected to the connection structure;
a second semiconductor chip mounted on the second substrate; and
a second connection pattern electrically connecting the second semiconductor chip to the second substrate.

6. The device of claim 5, wherein:
the first semiconductor chip comprises logic cells; and
the second semiconductor chip comprises memory cells.
The device of claim 1, wherein the first and second semiconductor packages include chips of different types from each other.

8. A semiconductor package device, comprising:
a first semiconductor package including:
a first substrate; and
a first semiconductor chip mounted on the first substrate;
a second semiconductor package including:
a second substrate; and
a second semiconductor chip mounted on the second substrate; and
a package substrate;
wherein:
the first semiconductor chip is electrically connected to the second semiconductor chip through the first substrate and the second substrate; and
the first semiconductor chip is electrically connected to the package substrate.

9. The semiconductor package device of claim 8, wherein:
the first substrate includes a plurality of first pads;
the second substrate includes a plurality of second pads; and
each first pad is aligned with a corresponding one of the second pads.

10. The semiconductor package device of claim 9, wherein each first pad is electrically connected to the corresponding one of the second pads by a solder ball.

11. The semiconductor package device of claim 8, wherein an active surface of the first semiconductor chip faces the package substrate.

12. The semiconductor package device of claim 11, wherein the first semiconductor chip is electrically connected to the first substrate by a plurality of bonding wires.

13. The semiconductor package device of claim 8, wherein the second semiconductor package further comprises at least another second semiconductor chip electrically connected to the second substrate.

14. The semiconductor package device of claim 13, wherein the second semiconductor chips of the second semiconductor package are stacked on the second substrate.

15. The semiconductor package device of claim 8, wherein a width of the first substrate is substantially similar to a width of the second substrate.

16. The semiconductor package device of claim 8, wherein a width of the first substrate is different from a width of the package substrate.

17. The semiconductor package device of claim 8, further comprising a first molding part disposed on the package substrate and including a surface substantially coplanar with a surface of the first substrate.

18. The semiconductor package device of claim 17, wherein the second semiconductor package further comprises a second molding part disposed on the second substrate.

19. A system, comprising:
a processor; and
a memory coupled to the processor, the memory including:
a first semiconductor package including:
a first substrate; and
a first semiconductor chip mounted on the first substrate;
a second semiconductor package including:
a second substrate; and
a second semiconductor chip mounted on the second substrate; and
a package substrate;
wherein:
the first semiconductor chip is electrically connected to the second semiconductor chip through the first substrate and the second substrate; and
the first semiconductor chip is electrically connected to the package substrate.

20. The system of claim 19, wherein:
the second semiconductor chip includes memory cells; and
the first semiconductor chip includes logic cells configured to control the second semiconductor chip.
